(19) United States
(12) Patent Application Publication
(10) Pub. No.: US 2026/0269556 A1
(43) Pub. Date: Sep. 10, 2026

(54) WAVELENGTH TUNABLE LASER AND OPTICAL FILTER

(71) Applicants: Sumitomo Electric Industries, Ltd., Osaka (JP); HOSEI UNIVERSITY, Tokyo (JP)

(72) Inventors: Naoki FUJIWARA, Osaka (JP); Takuo HIRATANI, Osaka (JP); Kento KOMATSU, Osaka (JP); Yusuke SAWADA, Osaka (JP); Takuya MITARAI, Osaka (JP); Takeshi FUJISAWA, Tokyo (JP); Hideki YAGI, Osaka (JP)

(73) Assignees: Sumitomo Electric Industries, Ltd., Osaka (JP); HOSEI UNIVERSITY, Osaka (JP)

(21) Appl. No.: 19/468,492

(22) Filed: Feb. 3, 2026

(30) Foreign Application Priority Data
Feb. 5, 2025 (JP) 2025-017691
Sep. 29, 2025 (JP) 2025-162294

(51) Int. Cl. H01S 3/083; H01S 3/063; H01S 3/102

(52) U.S. Cl. CPC H01S 3/083; H01S 3/063; H01S 3/1028

(57) ABSTRACT

A wavelength tunable laser includes a first gain section having an optical gain and emitting light of a first band, a second gain section having an optical gain and emitting light of a second band, an optical filter provided at a substrate, a first reflection portion and a second reflection portion that reflect the light of the first band, and a third reflection portion and a fourth reflection portion that reflect the light in the second band. The optical filter includes a first region including first to third waveguides, a second region including fourth to sixth waveguides, a first ring resonator, and a second ring resonator. The first waveguide, and the first and the second ring resonators are provided between the first and the second reflections portion. The fourth waveguide, and the first and the second ring resonators are provided between the third and the fourth reflection portions.

### CROSS REFERENCE TO RELATED APPLICATIONS

This application claims priority based on Japanese Patent Applications No. 2025-017691 filed on Feb. 5, 2025 and No. 2025-162294 filed on Sep. 29, 2025, and the entire contents of the Japanese patent applications are incorporated herein by reference.

### TECHNICAL FIELD

The present disclosure relates to a wavelength tunable laser and an optical filter.

### BACKGROUND

Wavelength tunable lasers are used for applications such as communication. There is a technique of forming a hybrid light source by bonding an element having an optical gain to a silicon on insulator (SOI) substrate or the like (non-patent literature 1: Takuo Hiratani et. al., “SOA Integrated InP/Si Hybrid Tunable Laser by Utilizing Chip-on-Wafer Hybdrophilic Bonding” 2024 IEEE Silicon Photonics Conference, Proceedings ThB5, 2024, and non-patent literature 2: Takuo Hiratani et al., “Hybrid tunable lasers with InP-based gain region bonded on Si-slab waveguide structure”, 2024 The Institute of Electronics, Information and Communication Engineers General Conference, C-3_4-37). A technique of butt-joint joining a laser element to a filter has also been developed (non-patent literature 3: Kissho Iwanaga, Yuga Tomimura and Tomohiro Kita “Hybrid laser diode with ultrawide wavlelength-tunable range using curved directional couplers” Optics Express Vol. 31, No. 21, pp. 34946-34953, October 9, 2023). The substrate is provided with optical elements such as a waveguide and a ring resonator. Light generated from the element propagates to a waveguide or the like.

### SUMMARY OF INVENTION

A wavelength tunable laser according to the present disclosure includes a first gain section having an optical gain and emitting light of a first band, a second gain section having an optical gain and emitting light of a second band, an optical filter provided at a substrate, a first reflection portion and a second reflection portion each of which reflects the light of the first band, and a third reflection portion and a fourth reflection portion each of which reflects the light in the second band. The optical filter includes a first region configured to allow the light of the first band to propagate, a second region configured to allow the light of the second band to propagate, a first ring resonator, and a second ring resonator. The first gain section is optically coupled to the first region. The second gain section is optically coupled to the second region. The first region includes a first waveguide, a second waveguide, and a third waveguide. The second region includes a fourth waveguide, a fifth waveguide, and a sixth waveguide. Each of the first waveguide and the fourth waveguide is optically coupled to the first ring resonator and the second ring resonator. Each of the second waveguide and the fifth waveguide is optically coupled to the first ring resonator. Each of the third waveguide and the sixth waveguide is optically coupled to the second ring resonator. The first waveguide, the first ring resonator, and the second ring resonator are provided between the first reflection portion and the second reflection portion in a propagating direction of light. The fourth waveguide, the first ring resonator, and the second ring resonator are provided between the third reflection portion and the fourth reflection portion in a propagating direction of light.

### BRIEF DESCRIPTION OF THE DRAWINGS

FIG. 1 is a plan view illustrating a wavelength tunable laser according to a first embodiment.

FIG. 2A is a cross-sectional view illustrating a wavelength tunable laser.

FIG. 2B is a cross-sectional view illustrating a wavelength tunable laser.

FIG. 3 is a diagram illustrating a reflectance spectrum.

FIG. 4A is a plan view illustrating an example of light propagation.

FIG. 4B is a plan view illustrating an example of light propagation.

FIG. 4C is a plan view illustrating an example of light propagation.

FIG. 4D is a plan view illustrating an example of light propagation.

FIG. 5A is a plan view illustrating a multiplexer.

FIG. 5B is a cross-sectional view illustrating a multiplexer.

FIG. 6 is a diagram illustrating characteristics of a multiplexer.

FIG. 7 is a plan view illustrating a wavelength tunable laser according to a comparative example.

FIG. 8 is a plan view illustrating a wavelength tunable laser according to a second embodiment.

FIG. 9 is a plan view illustrating a wavelength tunable laser according to a third embodiment.

FIG. 10 is a plan view illustrating a band-pass filter.

FIG. 11 is a diagram illustrating transmittance.

FIG. 12A is a diagram illustrating an optical spectrum when only a laser portion of an L-band is driven without driving a laser portion of a C-band.

FIG. 12B is a diagram illustrating an optical spectrum when only a laser portion of an L-band is driven without driving a laser portion of a C-band.

FIG. 13 is a plan view illustrating a wavelength tunable laser according to a fourth embodiment.

### DESCRIPTION OF EMBODIMENTS

In optical communication, a plurality of wavelength ranges such as a C-band (from 1530 nm to 1565 nm) and an L-band (from 1565 nm to 1625 nm) are used. It is difficult to cover both wavelength bands with one wavelength tunable laser. The number of elements may also be increased to accommodate the two bands. However, there is a problem that the structure becomes complicated. Thus, it is an object of the present disclosure to provide a wavelength tunable laser and an optical filter which have a simple structure and can cover two bands.

According to the present disclosure, it is possible to provide a wavelength tunable laser and an optical filter which have a simple structure and can cover two bands.

### Description of Embodiments of Present Disclosure

The contents of the embodiments of the present disclosure will be listed and described first.
(1) A wavelength tunable laser according to one aspect of the present disclosure includes a first gain section having an optical gain and emitting light of a first band, a second gain section having an optical gain and emitting light of a second band, an optical filter provided at a substrate, a first reflection portion and a second reflection portion, each of which reflects the light of the first band, and a third reflection portion and a fourth reflection portion, each of which reflects the light in the second band. The optical filter includes a first region configured to allow the light of the first band to propagate, a second region configured to allow the light of the second band to propagate, a first ring resonator, and a second ring resonator. The first gain section is optically coupled to the first region. The second gain section is optically coupled to the second region. The first region includes a first waveguide, a second waveguide, and a third waveguide. The second region includes a fourth waveguide, a fifth waveguide, and a sixth waveguide. The first waveguide and the fourth waveguide are each optically coupled to the first ring resonator and the second ring resonator. The second waveguide and the fifth waveguide are each optically coupled to the first ring resonator. The third waveguide and the sixth waveguide are each optically coupled to the second ring resonator. The first waveguide, the first ring resonator, and the second ring resonator are provided between the first reflection portion and the second reflection portion in a propagating direction of light. The fourth waveguide, the first ring resonator, and the second ring resonator are provided between the third reflection portion and the fourth reflection portion in a propagating direction of light. The emitted light of the first gain section propagates through the first region. The emitted light of the second gain section propagates through the second region. The wavelength tunable laser can cover two bands. The first region and the second region share the first ring resonator and the second ring resonator. The structure is simplified.
(2) In the above (1), the first waveguide and the second waveguide may be located opposite each other across the first ring resonator and extend in a same direction from the first ring resonator. The fourth waveguide and the fifth waveguide may be located opposite each other across the first ring resonator and extend in a same direction from the first ring resonator. The first waveguide and the third waveguide may be located opposite each other across the second ring resonator and extend in a same direction from the second ring resonator. The fourth waveguide and the sixth waveguide may be located opposite each other across the second ring resonator and extend in a same direction from the second ring resonator. The emitted light of the first gain section is transferred between the first waveguide, the first ring resonator, and the second waveguide, and is transferred between the first waveguide, the second ring resonator, and the third waveguide. The emitted light of the second gain section is transferred between the fourth waveguide, the first ring resonator, and the fifth waveguide, and is transferred between the fourth waveguide, the second ring resonator, and the sixth waveguide. The emitted light of the first gain section propagates through the first region. The emitted light of the second gain section propagates through the second region. The wavelength tunable laser can cover two bands.
(3) In the above (1) or (2), the fourth waveguide may extend from the first ring resonator and the second ring resonator in a direction opposite to a direction in which the first waveguide extends. The fifth waveguide may extend from the first ring resonator in a direction opposite to a direction in which the second waveguide extends. The sixth waveguide may extend from the second ring resonator in a direction opposite to a direction in which the third waveguide extends. The emitted light of the first gain section is less likely to leak to the second region. The emitted light of the second gain section is less likely to leak to the first region. The loss of light can be reduced.
(4) In any one of the above (1) to (3), the first reflection portion may be a loop mirror provided in the second waveguide. The second reflection portion may be a loop mirror provided in the third waveguide. The third reflection portion may be a loop mirror provided in the fifth waveguide. The fourth reflection portion may be a loop mirror provided in the sixth waveguide. The first gain section and the second gain section may be bonded to one surface of the substrate. The first gain section may be provided at a position overlapping the first waveguide and is optically coupled to the first waveguide. The second gain section may be provided at a position overlapping the fourth waveguide and is optically coupled to the fourth waveguide. A laser resonator is formed in each of the first region and the second region. The emitted light of the first gain section and the emitted light of the second gain section are laser-oscillated.
(5) In any one of the above (1) to (4), the first reflection portion may be a loop mirror provided in the second waveguide. The third reflection portion may be a loop mirror provided in the fifth waveguide. The first gain section and the second gain section may be butt-jointed to the substrate. The first gain section may be optically coupled to the third waveguide. The second gain section may be optically coupled to the sixth waveguide. The second reflection section may be a reflection coat provided opposite the optical filter with respect to the first gain section. The fourth reflection portion may be a reflection coat provided opposite the optical filter with respect to the second gain section. The laser resonator is formed in each of the first region and the second region. The emitted light of the first gain section and the emitted light of the second gain section are laser-oscillated.
(6) In any one of the above (1) to (5), the optical filter may include a multiplexer, a seventh waveguide and an eighth waveguide. The second waveguide may be optically coupled to a first input end of the multiplexer. The fifth waveguide may be optically coupled to a second input end of the multiplexer. The seventh waveguide may be optically coupled to a first output end of the multiplexer. The eighth waveguide may be optically coupled to a second output end of the multiplexer. Light can be emitted from the seventh waveguide and the eighth waveguide.
(7) In the above (6), the multiplexer may be a mosaic element. Light can be emitted from the seventh waveguide and the eighth waveguide. Light returning to the second waveguide and the fifth waveguide can be reduced.
(8) In any one of the above (1) to (7), the wavelength tunable laser may further include a first heater provided on the first ring resonator, and a second heater provided on the second ring resonator. The wavelength can be easily adjusted by changing the refractive indices of the first ring resonator and the second ring resonator.
(9) In any one of the above (1) to (8), the substrate may have a silicon layer or a silicon nitride layer. The first waveguide, the second waveguide, the third waveguide, the fourth waveguide, the fifth waveguide, the sixth waveguide, the first ring resonator, and the second ring resonator may be provided in the silicon layer or the silicon nitride layer. By confining light in the waveguide and the ring resonator, the loss of light can be reduced.
(10) In any one of the above (1) to (8), the second band may be a band having a longer wavelength than the first band. The wavelength tunable laser may include a band-pass filter. The band-pass filter may have a first port, a second port, and a third port. The first port and the second port may be connected to the first waveguide. In the first band, a transmittance between the first port and the second port may be higher than a transmittance between the first port and the third port. In the second band, a transmittance between the first port and the third port may be higher than a transmittance between the first port and the second port. It is possible to prevent abnormal oscillation.
(11) In the above (10), the band-pass filter may be a mosaic element. The band-pass filter can be downsized.
(12) An optical filter includes a first region, a second region, a first ring resonator, and a second ring resonator. The first region includes a first waveguide, a second waveguide, and a third waveguide. The second region includes a fourth waveguide, a fifth waveguide, and a sixth waveguide. Each of the first waveguide and the fourth waveguide is optically coupled to the first ring resonator and the second ring resonator. Each of the second waveguide and the fifth waveguide is optically coupled to the first ring resonator. Each of the third waveguide and the sixth waveguide is optically coupled to the second ring resonator. The optical filter can cover two bands. The structure is simplified.

### Details of Embodiments of Present Disclosure

Specific examples of a wavelength tunable laser and an optical filter according to an embodiment of the present disclosure will be described below with reference to the drawings. The present disclosure is not limited to these examples, but is defined by the scope of the claims, and is intended to include all modifications within the meaning and scope equivalent to the scope of the claims.

### First Embodiment

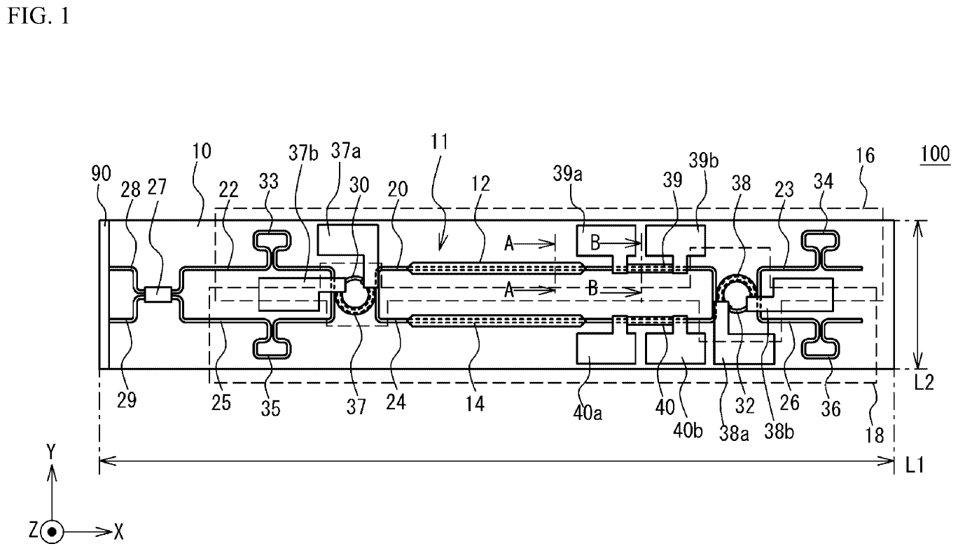

FIG. 1 is a plan view illustrating a wavelength tunable laser 100 according to a first embodiment. The wavelength tunable laser 100 is a hybrid laser element, and includes a substrate 10, a gain section 12 (first gain section), and a gain section 14 (second gain section). The two sides of the substrate 10 are parallel to an X-axis direction. The other two sides are parallel to a Y-axis direction. The upper surface of the substrate 10 is parallel to an XY plane. A Z-axis direction is a normal direction of the upper surface and is a thickness direction of the substrate 10. The X-axis direction, the Y-axis direction, and the Z-axis direction are orthogonal to each other. A length L1 of the substrate 10 in the X-axis direction is, for example, 0.6 mm. A length L2 of the substrate 10 in the Y-axis direction is, for example, 2.5 mm.

An optical filter 11 is formed on the substrate 10. The optical filter 11 includes a region 16 (first region), a region 18 (second region), a multiplexer 27, a waveguide 28 (seventh waveguide), and a waveguide 29 (eighth waveguide). In FIG. 1, each region is indicated by a dashed line. The gain section 12 and the gain section 14 are bonded to the substrate 10. The gain section 12 is bonded to the region 16 of the optical filter 11. The gain section 14 is bonded to the region 18 of the optical filter 11. Each of the gain sections 12 and 14 has tapered portions at both ends in the X-axis direction. The tapered portions are located on a waveguide 20 or 24. The length of each of the gain sections 12 and 14 in the X-axis direction is, for example, 50 μm.

The wavelength tunable laser 100 may emit light of two wavelength bands. The gain section 12 and the region 16 correspond to one band, and form a laser resonator corresponding to, for example, a C-band (wavelength of 1530 nm to 1565 nm, first band). The gain section 14 and the region 18 form a laser resonator corresponding to a wavelength band other than the C-band, for example, a part of an L-band (second band) (wavelength of 1565 nm to 1600 nm). The light of the wavelength tunable laser 100 is, for example, a single mode. The laser light is emitted from the waveguide 28 and the waveguide 29. The wavelength tunable laser 100 has an antireflection coat 90 on a light emitting end face. The end face of the waveguide 28 and the end face of the waveguide 29 are covered with the antireflection coat 90.

The region 16 of the optical filter 11 includes the waveguide 20 (first waveguide), a waveguide 22 (second waveguide), and a waveguide 23 (third waveguide). The region 18 includes the waveguide 24 (fourth waveguide), a waveguide 25 (fifth waveguide), and a waveguide 26 (sixth waveguide). The region 16 and the region 18 share a ring resonator 30 (first ring resonator) and a ring resonator 32 (second ring resonator). The width of each of the waveguides 20, and 22 to 26 is, for example, 500 nm. Each of the ring resonators 30 and 32 is formed of a ring-shaped waveguide such as an annular ring. The circumference of the ring resonator 30 is different from the circumference of the ring resonator 32. The circumference of the ring resonator 30 is, for example, 140 μm. The circumference of the ring resonator 32 is, for example, 150 μm.

In the example of FIG. 1, each of the waveguides 20, 22, 23, 24, 25, 26, 28 and 29 has a portion parallel to the X-axis and a portion parallel to the Y-axis. The shape of the waveguide may vary from the example of FIG. 1, e.g., it may not be parallel to the X-axis and Y-axis, it may include portions that are angled from the X-axis and Y-axis, or it may include curves, etc.

The waveguide 20 and the waveguide 24 are located between the ring resonator 30 and the ring resonator 32. The waveguide 20 and the waveguide 24 are connected to each other near the ring resonator 30 and the ring resonator 32, thereby forming a loop-type waveguide. The portion of the waveguide 20 parallel to the X-axis and the portion of the waveguide 24 parallel to the X-axis are separated from each other.

The portions of the waveguides 20 and 24 parallel to the Y-axis are optically coupled to the ring resonators 30 and 32. For example, the portions of the waveguide 20 and the waveguide 24 parallel to the Y-axis may be close to the ring resonator 30 and the ring resonator 32, respectively, to form directional couplers. The waveguide 20 and the waveguide 24 extend in opposite directions from the ring resonator 30. The waveguide 20 and the waveguide 24 extend in opposite directions from the ring resonator 32.

The waveguide 22 is provided at a position opposite to the waveguide 20 with respect to the ring resonator 30 in the X-axis direction. The waveguide 25 is provided at a position opposite to the waveguide 24 with respect to the ring resonator 30. A portion of the waveguide 22 parallel to the X-axis and a portion of the waveguide 25 parallel to the X-axis are separated from each other. The portions of the waveguide 22 and the waveguide 25 parallel to the Y-axis are optically coupled to the ring resonator 30. The waveguide 22 and the waveguide 25 extend from the ring resonator 30 in opposite directions. The waveguide 20 and the waveguide 22 extend in the same direction (upward in FIG. 1) with respect to the ring resonator 30. The waveguide 24 and the waveguide 25 extend in the same direction (downward in FIG. 1) with respect to the ring resonator 30.

The waveguide 22 and the waveguide 25 extend from the ring resonator 30 to the multiplexer 27. A loop mirror 33 (first reflection portion) is provided in the middle of the waveguide 22. The waveguide 22 is curved, and the waveguides 22 come close to each other near the end point of the curve to form a directional coupler, thereby forming the loop mirror 33. A loop mirror 35 (third reflection portion) is provided in the middle of the waveguide 25. The reflectance of the loop mirror 33 with respect to the light in the C-band is, for example, 90% or more. The reflectance of the loop mirror 35 with respect to the light in the L-band is, for example, 90% or more.

The multiplexer 27 is, for example, an element with two inputs and two outputs. The waveguide 22 is optically coupled to a first input end of the multiplexer 27. The waveguide 25 is optically coupled to a second input end of the multiplexer 27. The waveguide 28 is optically coupled to a first output end of the multiplexer 27 and extends to the end portion of the substrate 10. The waveguide 29 is optically coupled to a second output end of the multiplexer 27 and extends to the end portion of the substrate 10.

The waveguide 23 is provided at a position opposite to the waveguide 20 with respect to the ring resonator 32 in the X-axis direction. The waveguide 26 is provided at a position opposite to the waveguide 24 with respect to the ring resonator 32. A portion of the waveguide 23 parallel to the X-axis and a portion of the waveguide 26 parallel to the X-axis are separated from each other. The portions of the waveguide 23 and the waveguide 26 parallel to the Y-axis are optically coupled to the ring resonator 32. The waveguide 23 and the waveguide 26 extend from the ring resonator 32 in opposite directions. The waveguide 20 and the waveguide 23 extend in the same direction from the ring resonator 32. The waveguide 24 and the waveguide 26 extend from the ring resonator 32 in the same direction.

The waveguide 23 and the waveguide 26 do not extend to the end portion of the substrate 10, and terminate before the end portion. A loop mirror 34 (second reflection portion) is provided in the middle of the waveguide 23. A loop mirror 36 (fourth reflection portion) is provided in the middle of the waveguide 26. The reflectance of the loop mirror 34 with respect to the light in the C-band is, for example, 90% or more. The reflectance of the loop mirror 36 with respect to the light in the L-band is, for example, 90% or more.

A heater 37 (first heater) is provided on the ring resonator 30. A heater 38 (second heater) is provided on the ring resonator 32. A heater 39 is provided on the waveguide 20. A heater 40 is provided on the waveguide 24. A plurality of pads are provided at the substrate 10. A pad 37a and a pad 37b are electrically connected to the heater 37. A pad 38a and a pad 38b are electrically connected to the heater 38. A pad 39a and a pad 39b are electrically connected to the heater 39. A pad 40a and a pad 40b are electrically connected to the heater 40. The heater is made of metal, for example, platinum (Pt). The pad is made of metal, for example, gold (Au).

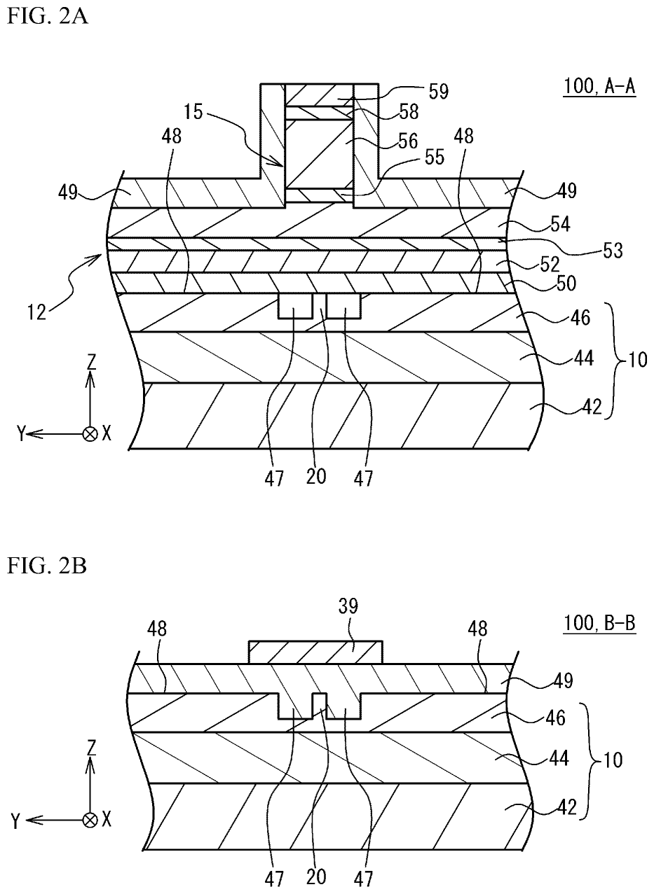

FIGS. 2A and 2B are cross-sectional views illustrating the wavelength tunable laser 100. FIG. 2A illustrates a cross-section taken along the line A-A in FIG. 1. FIG. 2B illustrates a cross-section taken along the line B-B of FIG. 1. As illustrated in FIGS. 2A and 2B, the substrate 10 is an SOI substrate and includes a substrate 42, a box layer 44, and a silicon layer 46. The box layer 44 is stacked on one surface of the substrate 42. The silicon layer 46 is stacked on a surface of the box layer 44 opposite to the substrate 42. The substrate 42 and the silicon layer 46 are formed of silicon (Si). The box layer 44 is formed of an insulating material such as silicon oxide (SiO₂). The thickness of the silicon layer 46 is, for example, 220 nm. The refractive index of the silicon layer 46 is 3.45. The refractive indices of the box layer 44 and a cladding layer 49 described later are 1.45, which are lower than the refractive index of the silicon layer 46. These refractive indices are values for light having a wavelength of 1.55 μm.

The silicon layer 46 has the waveguide 20, recessed portions 47, and terraces 48. The recessed portions 47 are grooves extending along the waveguide 20 and are located on both sides of the waveguide 20 and between the waveguide 20 and the terraces 48. The terraces 48 are plate-shaped portions located outside the recessed portions 47.

As illustrated in FIGS. 2A and 2B, the upper surfaces of the waveguide 20 and the terraces 48 have the same height in the Z-axis direction. The recessed portions 47 are recessed from the upper surfaces of the waveguide 20 and the terraces 48. The recessed portions 47 may extend to the middle of the silicon layer 46 in the Z-axis direction, or may penetrate the silicon layer 46. In the cross-section of FIG. 2A, the recessed portions 47 are filled with air. In the cross-section of FIG. 2B, the recessed portions 47 are filled with the same material (SiO₂) as the cladding layer 49. The other waveguides and ring resonators have the described-above structure.

As illustrated in FIG. 2A, the gain section 12 is bonded to the silicon layer 46 of the substrate 10. The gain section 12 has a mesa 15. The mesa 15 protrudes from the substrate 10 in the Z-axis direction and is located above the waveguide 20.

The gain section 12 includes a damage relaxation layer 50, a cladding layer 52, an optical confinement layer 53, an active layer 54, an optical confinement layer 55, a cladding layer 56, and a contact layer 58. The damage relaxation layer 50 is bonded to the upper surface of the silicon layer 46. The damage relaxation layer 50 may be in contact with the upper surface of the silicon layer 46. An adhesive layer such as a resin may be provided between the damage relaxation layer 50 and the silicon layer 46. The cladding layer 52, the optical confinement layer 53, and the active layer 54 are stacked in this order on a surface of the damage relaxation layer 50 opposite to the silicon layer 46. The damage relaxation layer 50, the cladding layer 52, the optical confinement layer 53, and the active layer 54 are located under the mesa 15 and extend outside the mesa 15. The mesa 15 includes the active layer 54, the optical confinement layer 55, the cladding layer 56, and the contact layer 58. A part of the active layer 54 protrudes in the Z-axis direction. The optical confinement layer 55, the cladding layer 56, and the contact layer 58 are stacked on the protruding portion of the active layer 54.

The damage relaxation layer 50, the optical confinement layer 53, and the optical confinement layer 55 are formed of, for example, undoped gallium indium arsenide phosphide (i-GaInAsP). The thickness of the damage relaxation layer 50 is, for example, 200 nm. The thicknesses of the optical confinement layer 53 and the optical confinement layer 55 are, for example, 100 nm. The band gap wavelengths of the damage relaxation layer 50, the optical confinement layer 53, and the optical confinement layer 55 are, for example, 1.2 μm, which are shorter than the wavelength of the emitted light of the gain section 12.

The cladding layer 52 is formed of, for example, n-type indium phosphide (n-InP). The thickness of the cladding layer 52 is, for example, 200 nm. As an n-type dopant, for example, Si is doped. The dopant concentration of the cladding layer 52 is, for example, 1×10¹⁹ cm⁻³. The cladding layer 56 is formed of, for example, p-type InP (p-InP). The thickness of the cladding layer 56 is, for example, 1500 nm. The contact layer 58 is formed of, for example, (p+)-type gallium indium arsenide ((p+)-GaInAs). For example, zinc (Zn) is doped as a p-type dopant. The dopant concentration of the cladding layer 56 is, for example, 1×10¹⁸ cm⁻³. The dopant concentration of the contact layer 58 is, for example, 1×10¹⁹ cm⁻³.

The active layer 54 has a multi quantum well (MQW) structure and includes a plurality of well layers and a plurality of barrier layers. The well layers and the barrier layers are alternately stacked. One well layer is formed of, for example, gallium indium arsenide phosphide (GaInAsP) having a thickness of 6 nm. One barrier layer is formed of, for example, GaInAsP having a thickness of 10 nm.

The p-type cladding layer 56, the p-type contact layer 58, the i-type active layer 54, and the n-type cladding layer 52 are stacked to form a pin (positive-intrinsic-negative) junction. The mesa 15 functions as a current confinement structure.

The cladding layer 49 is formed of, for example, SiO₂. The thickness is, for example, 1 μm. The cladding layer 49 covers the surfaces of the gain section 12 and the silicon layer 46. The cladding layer 49 covers the side and top surfaces of the mesa 15. The cladding layer 49 has an opening above the mesa 15.

An electrode 59 is provided on the mesa 15 and is electrically connected to the contact layer 58. The electrode 59 is formed of, for example, a laminate of titanium, platinum, and gold (Ti/Pt/Au). An electrode (not shown) is electrically connected to the cladding layer 52. The electrode is formed of, for example, an alloy of gold, germanium, and Ni (AuGeNi).

The gain section 14 has the same configuration as the gain section 12. The active layer 54 of the gain section 12 is designed to have an optical gain in the C-band, for example. The active layer 54 of the gain section 14 is designed to have an optical gain in the L-band, for example. The wavelength tunable range of the gain section 12 includes the C-band. The wavelength tunable range of the gain section 14 includes the L-band.

As illustrated in FIG. 2B, at the position where the gain section 12 is not bonded, the cladding layer 49 covers the upper surface of the silicon layer 46. The heater 39 is provided on a surface of the cladding layer 49 opposite to the substrate 10.

The wavelength tunable laser 100 can emit light in the C-band and light in the L-band. When the light in the C-band is emitted, a voltage is applied to the gain section 12, and carriers are injected into the active layer 54 of the gain section 12. Light is emitted from both ends of the gain section 12. The gain section 12 is evanescently coupled to the waveguide 20, and light is transferred from the gain section 12 to the waveguide 20.

The light emitted from the first end portion of the gain section 12 propagates through the waveguide 20, circulates through the ring resonator 30 several times, and then is transferred to the waveguide 22. A part of the light is reflected from the loop mirror 33 provided in the waveguide 22, propagates through the ring resonator 30 and the waveguide 20, and returns to the gain section 12. The light emitted from the second end portion of the gain section 12 propagates through the waveguide 20, circulates through the ring resonator 32 several times, and then is transferred to the waveguide 23. A part of the light is reflected from the loop mirror 34 provided in the waveguide 23, propagates through the ring resonator 32 and the waveguide 20, and returns to the gain section 12. The light is repeatedly reflected from the loop mirror 33 and the loop mirror 34, and laser oscillation occurs. The emitted light of the gain section 14 is repeatedly reflected from the loop mirror 35 and the loop mirror 36, and laser oscillation occurs. The oscillation wavelength of light is determined by the ring resonator.

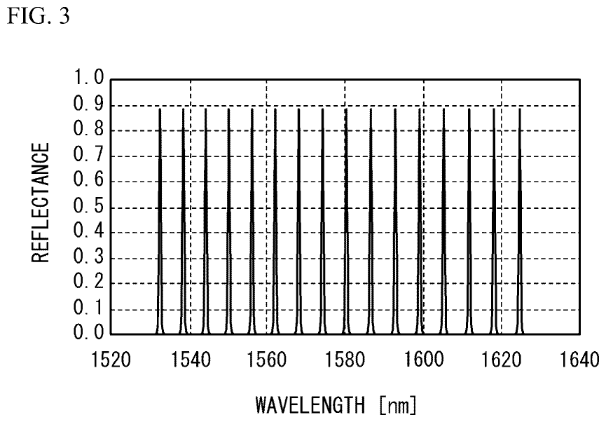

FIG. 3 illustrates a reflection spectrum. The horizontal axis represents the wavelength of light. The vertical axis represents the reflectance of light that circulates through each of the ring resonators 30 and 32 and is reflected from each of the loop mirrors 33 to 36. As illustrated in FIG. 3, peaks occur periodically and theoretically exist infinitely at regular intervals. The light is resonated by each of the ring resonators 30 and 32. A peak occurs at the resonant wavelength. The wavelength of the peak depends on the circumference of each of the ring resonators 30 and 32.

The oscillation wavelength is determined by the vernier effect of the ring resonator 30 and the ring resonator 32. In the region 16 of the optical filter 11, reflected light is generated from the ring resonator 30 and the loop mirror 33. Reflected light is also generated from the ring resonator 32 and the loop mirror 34. The circumference of the ring resonator 30 is different from the circumference of the ring resonator 32. The peaks of the spectra of the two reflected lights coincide at a certain wavelength. The light is laser-oscillated at the wavelength. The vernier effect as described above is also used in the region 18.

As illustrated in FIG. 1, the ring resonator 30 is provided with the heater 37. The ring resonator 32 is provided with the heater 38. The heaters 37 and 38 generate heat when currents flow through the heaters 37 and 38, respectively. The ring resonators 30 and 32 are heated by the heat generated by the heaters 37 and 38. The refractive index of each of the ring resonators 30 and 32 changes due to a temperature change, and the spectrum changes. The wavelength of the laser light can be changed. The heater 39 is provided in the waveguide 20. The heater 40 is provided in the waveguide 24. By heating the waveguides 20 and 24 using these heaters 39 and 40, it is also possible to finely adjust the phase of the light. The relationship between the power input to the heaters 37 to 40 and the amount of change in the resonance wavelength of light is investigated by a test or the like.

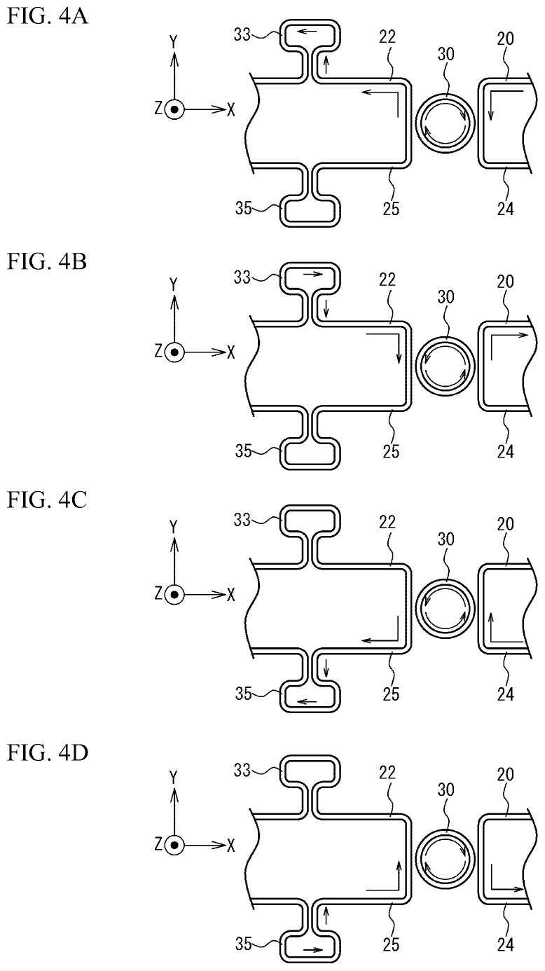

FIGS. 4A to 4D are plan views illustrating examples of light propagation, and illustrate enlarged views near the ring resonator 30 and the loop mirror 33. Arrows in the figure represent the direction of light.

In FIG. 4A, light propagates through the waveguide 20 and is transferred to the ring resonator 30. The light circulates clockwise through the ring resonator 30. The light circulates several times through the ring resonator 30 and is transferred to the waveguide 22. Ideally, no light is transferred from the ring resonator 30 to the waveguide 25.

As illustrated in FIG. 4B, the light is reflected from the loop mirror 33 provided in the waveguide 22. Light is transferred from the waveguide 22 to the ring resonator 30. The light circulates counterclockwise through the ring resonator 30. The light circulates several times through the ring resonator 30 and is transferred to the waveguide 22. Ideally, no light is transferred from the ring resonator 30 to the waveguide 24.

In FIG. 4C, light propagates through the waveguide 24 and onto the ring resonator 30. The light circulates counterclockwise through the ring resonator 30. The light circulates several times through the ring resonator 30 and is transferred to the waveguide 25. Ideally, no light is transferred from the ring resonator 30 to the waveguide 22.

As illustrated in FIG. 4D, the light is reflected from the loop mirror 35 provided in the waveguide 25. The light is transferred from the waveguide 25 to the ring resonator 30. The light circulates clockwise through the ring resonator 30. The light circulates several times through the ring resonator 30 and is transferred to the waveguide 24. Ideally, no light is transferred from the ring resonator 30 to the waveguide 20.

The light propagating through the waveguide 20 toward the ring resonator 32 is transferred from the waveguide 20 to the ring resonator 32, and is transferred from the ring resonator 32 to the waveguide 23. The light is reflected from the loop mirror 34 provided in the waveguide 23 and returns to the waveguide 20. This light ideally does not propagate through waveguide 24 and the waveguide 26. The light propagating through the waveguide 24 toward the ring resonator 32 is transferred from the waveguide 22 to the ring resonator 32 and from the ring resonator 32 to the waveguide 26. The light is reflected from the loop mirror 36 provided in the waveguide 26 and returns to the waveguide 24. This light ideally does not propagate through the waveguide 20 and the waveguide 23.

As described above, in principle, the light emitted from the gain section 12 propagates through the waveguide 20, the ring resonator 30, the ring resonator 32, the waveguide 22, and the waveguide 23, but does not propagate through the waveguide 24, the waveguide 25, and the waveguide 26. The light emitted from the gain section 14 propagates through the waveguide 24, the ring resonator 30, the ring resonator 32, the waveguide 25, and the waveguide 26, but does not propagate through the waveguide 20, the waveguide 22, and the waveguide 23. That is, the light in the C-band propagates through the region 16 of the optical filter 11 and does not propagate through the region 18. The light in the L-band propagates through the region 18 of the optical filter 11 and does not propagate through the region 16.

The waveguide 23 and the waveguide 26 terminate before the end portion of the substrate 10. Thus, light is not emitted from the waveguide 23 and the waveguide 26.

The light propagating through the waveguide 22 is input to the multiplexer 27, and is distributed from the multiplexer 27 to the waveguide 28 and the waveguide 29. The light propagating through the waveguide 25 is input to the multiplexer 27, and is distributed from the multiplexer 27 to the waveguide 28 and the waveguide 29. The waveguide 28 and the waveguide 29 extend to the end portion of the substrate 10. Light is emitted from the waveguide 28 and the waveguide 29.

For example, an optical fiber (not shown) is coupled to the waveguide 28. The light emitted from the optical fiber is input to a modulator or the like. The light emitted from the waveguide 29 is input to a device different from the modulator.

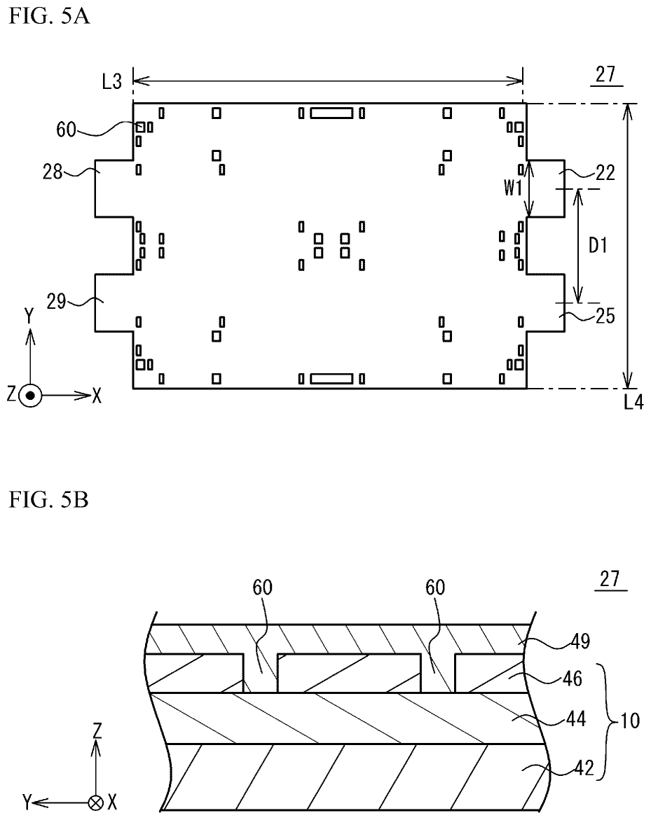

FIG. 5A is a plan view illustrating the multiplexer 27. The multiplexer 27 is a mosaic element provided at the substrate 10. The shape of the multiplexer 27 in the XY plane is rectangular. A length L3 of the multiplexer 27 in the X-axis direction is, for example, 10.5 μm. A length L4 of the multiplexer 27 in the Y-axis direction is, for example, 3 μm. The multiplexer 27 has a plurality of openings 60 provided in the silicon layer 46. In a plan view of the multiplexer 27, the shape of each of the plurality of openings 60 is, for example, circle. The shape of each of the plurality of openings 60 may be square, rectangular, elliptical, or the like. The plurality of openings form a mosaic pattern. In FIG. 5A, a large rectangle or square represents a region where the plurality of openings 60 are arranged. In FIG. 5A, the small rectangles represent regions where several openings 60 are arranged in one or two rows. In the example of FIG. 5A, the pattern of the plurality of openings 60 is line-symmetric with respect to a straight line passing through the center of the multiplexer 27 and parallel to the X-axis. Further, in the example of FIG. 5A, the pattern of the plurality of openings 60 is line-symmetric with respect to a straight line passing through the center of the multiplexer 27 and parallel to the Y-axis.

The right end portion of the multiplexer 27 in FIG. 5A is an input end, and the left end portion thereof is an output end. The waveguide 22 and the waveguide 25 are connected to the input end. A width W1 of the waveguide in the Y-axis direction is, for example, 0.6 μm. The waveguide 22 and the waveguide 25 are separated from each other in the Y-axis direction. A distance D1 between the center of the waveguide 22 and the center of the waveguide 25 in the Y-axis direction is, for example, 1.2 μm. The output end is connected to the waveguide 28 and the waveguide 29.

FIG. 5B is a cross-sectional view illustrating the multiplexer 27. The opening 60 extends from the upper surface of the silicon layer 46 to the upper surface of the box layer 44 along the Z-axis. The cladding layer 49 covers the upper surface of the silicon layer 46 and the opening 60. The inside of the opening 60 may be filled with the cladding layer 49 as in the example of FIG. 5B, or may be filled with air.

The refractive index of the opening 60 filled with the cladding layer 49 is different from the refractive index of the silicon layer 46. The light input to the multiplexer 27 is scattered in the plane of the multiplexer 27 and branched. A part of the light is output to the waveguide 28. Another part of the light is output to the waveguide 29.

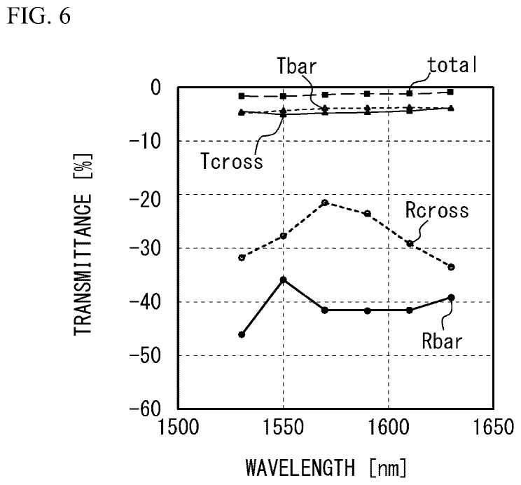

FIG. 6 is a diagram illustrating the characteristics of the multiplexer 27. The horizontal axis represents the wavelength of light. The vertical axis represents the transmittance of light. The black squares and dashed lines represent the sum (Total) of the transmittance to the two waveguides 28 and 29. The triangles and dotted lines represent the transmittance (Tbar) to one of the two waveguides 28 and 29. The triangles and solid lines represent the transmittance (Tcross) to the other of the two waveguides 28 and 29. The black circles and solid lines represent the fraction (Rbar) of light that returns to the waveguide itself that inputs the light. The open circles and dotted lines represent the transmittance (Rcross) to the other waveguide.

The wavelength of light in FIG. 6 is in a range from 1500 nm to 1650 nm, and include the C-band and L-band. In the C-band (1530 nm to 1565 nm), light is input from the waveguide 22 and is distributed to the waveguide 28 and the waveguide 29. Tbar represents the transmittance to the waveguide 28. Tcross represents the transmittance to the waveguide 29. Rbar represents the fraction of light reflected back into the waveguide 22. Rcross represents the fraction of light reflected back into the waveguide 25. In the L-band (1565 nm to 1625 nm), light is input from the waveguide 25 and distributed to the waveguide 28 and the waveguide 29. Tbar represents the transmittance to the waveguide 29. Tcross represents the transmittance to the waveguide 28. Rbar represents the fraction of light reflected back into the waveguide 25. Rcross represents the fraction of light reflected back into the waveguide 22.

As illustrated in FIG. 6, in the C-band and the L-band, the transmittance to the two waveguides 28 and 29 is-10 dB or more. The transmittance to the waveguide 28 and the transmittance to the waveguide 29 are substantially the same. The multiplexer 27 distributes the input light to the two waveguides 28 and 29 at a ratio of approximately 1:1. The distribution ratio may be other than 1:1.

The gain section 12 is for the C-band, and the gain section 14 is for the L-band. When one gain section is driven, the other gain section is not driven. Light may return from the multiplexer 27 to the gain section being driven. The phase of the returned light may affect the emitted light, and the deterioration of characteristics such as expansion of the spectral line width may occur. In FIG. 6, Rbar is −40 dB or less at most wavelengths. For example, the gain section 12 is driven, and light is input from the waveguide 22 to the multiplexer 27. Only a small amount of this light returns to the waveguide 22.

A part of the light input from the waveguide 22 is reflected to the waveguide 25. This light may be reflected from the loop mirror 35, input to the multiplexer 27 again, and return to the waveguide 22. As illustrated in FIG. 6, Rcross is −20 dB or less. Two reflections are made, one to the waveguide 25 and one to the waveguide 22 after re-input to the multiplexer 27. Rcross (−20 dB) is summed twice to give −40 dB. Thus, the intensity of the light returning to the waveguide 22 is reduced. The spectral line width is less likely to deteriorate. The expansion of the line width by the multiplexer 27 is, for example, about 10% of the line width before the input to the multiplexer 27.

### Comparative Example

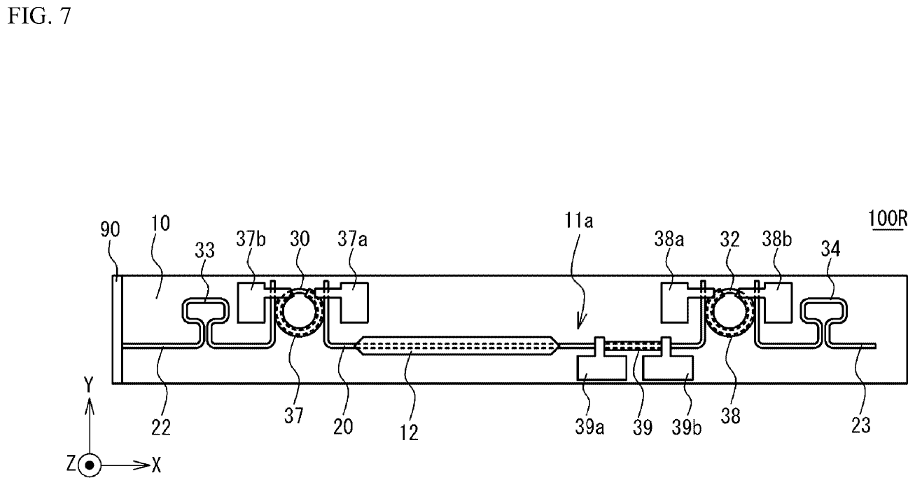

FIG. 7 is a plan view illustrating a wavelength tunable laser 100R according to a comparative example. The wavelength tunable laser 100R includes one gain section 12 and one optical filter 11a. The optical filter 11a includes the waveguide 20, the waveguide 22, the waveguide 23, the ring resonator 30, and the ring resonator 32. The optical filter 11a includes the heater 37, the heater 38, the heater 39, the pad 37a, the pad 37b, the pad 38a, the pad 38b, the pad 39a, and the pad 39b. The gain section 12 emits light in the C-band. The light in the C-band propagates through the optical filter 11a.

In order to emit light in the L-band in addition to the C-band, another wavelength tunable laser 100R corresponding to the L-band is used. Another optical filter corresponding to the L-band may be provided at the substrate 10, and another gain section corresponding to the L-band may be bonded thereto. However, the number of each of the waveguide, the ring resonator, the heater, and the pad is doubled. The configuration becomes complicated, and the wavelength tunable laser becomes large. The adjustment of the wavelength by the heater power becomes complicated.

According to the first embodiment, the wavelength tunable laser 100 includes the optical filter 11, and the two gain sections 12 and 14. The gain section 12 and the region 16 of the optical filter 11 are optically coupled to each other, and form a laser resonator corresponding to, for example, the C-band. The gain section 14 and the region 18 of the optical filter 11 are optically coupled to each other, and form a laser resonator corresponding to, for example, the L-band. The wavelength tunable laser 100 can cover the C-band and the L-band. The region 16 and the region 18 share the ring resonator 30 and the ring resonator 32. Thus, the configuration is simplified as compared with the case where two wavelength tunable lasers are arranged as illustrated in FIG. 7. The wavelength tunable laser 100 can be downsized.

The gain section 12 emits light having a wavelength in the C-band. The light propagates through the region 16 and is laser-oscillated. The gain section 14 emits light having a wavelength in the L-band. The light propagates through the region 18, and is laser-oscillated. In order to reduce the loss of light, it is important that the light in the C-band propagates through the region 16 and does not leak to the region 18. It is important that the light in the L-band propagates through the region 18 and does not leak to the region 16.

As illustrated in FIGS. 4A to 4D, the waveguide 20 and the waveguide 22 are located opposite to each other across the ring resonator 30 in the X-axis direction. The waveguide 20 and the waveguide 22 extend from the ring resonator 30 in the same direction in the Y-axis direction. The waveguide 24 and the waveguide 25 are located opposite to each other across the ring resonator 30 in the X-axis direction. The waveguide 24 and the waveguide 25 extend from the ring resonator 30 in the same direction and extend to the opposite side of the waveguide 20 and the waveguide 22 in the Y-axis direction.

As illustrated in FIG. 4A, the light that has been transferred from the waveguide 20 to the ring resonator 30 circulates clockwise through the ring resonator 30. The clockwise light is transferred from the ring resonator 30 to the waveguide 22, but is hardly transferred to the waveguide 25. As illustrated in FIG. 4B, the light reflected from the loop mirror 33 of the waveguide 22 circulates counterclockwise through the ring resonator 30. The counterclockwise light is transferred from the ring resonator 30 to the waveguide 20, but is hardly transferred to the waveguide 24. The light emitted from the gain section 12 propagates through the region 16 and is less likely to leak to the region 18. As illustrated in FIGS. 4C and 4D, light propagating between the waveguide 24, the ring resonator 30, and the waveguide 25 in the region 18 is less likely to leak to the region 16. The loss of light can be reduced.

The waveguide 20 and the waveguide 23 are located opposite to each other across the ring resonator 32, and extend from the ring resonator 32 in the same direction. The waveguide 24 and the waveguide 26 are located opposite to each other across the ring resonator 32, and extend from the ring resonator 32 in the same direction and further extend to the opposite side to the waveguide 20 and the waveguide 23. As in FIGS. 4A to 4D, light is less likely to leak between the region 16 and the region 18. The loss of light can be reduced.

The gain section 12 is bonded to the substrate 10 at a position overlapping the waveguide 20. The loop mirror 33 is provided in the waveguide 22. The loop mirror 34 is provided in the waveguide 23. The light emitted from the gain section 12 is reflected from the loop mirror 33 and the loop mirror 34, and travels back and forth between the two loop mirrors to occur laser oscillation. The gain section 14 is bonded to the substrate 10 at a position overlapping the waveguide 24. The loop mirror 35 is provided in the waveguide 25. The loop mirror 36 is provided in the waveguide 26. The light emitted from the gain section 14 is reflected from the loop mirror 35 and the loop mirror 36, and travels back and forth between the two loop mirrors to occur laser oscillation. A laser resonator is formed in each of the region 16 and the region 18. Laser light in each of the C-band and the L-band can be generated.

The optical filter 11 includes the multiplexer 27, the waveguide 28, and the waveguide 29. The multiplexer 27 branches the light in the C-band input from the waveguide 22 and outputs the branched light to the waveguide 28 and the waveguide 29. The multiplexer 27 branches the light in the L-band input from the waveguide 25 and outputs the branched light to the waveguide 28 and the waveguide 29. Laser light in the C-band and the L-band can be output from the waveguide 28 and the waveguide 29. The configuration for outputting light such as an optical fiber is simplified.

As illustrated in FIGS. 5A and 5B, the multiplexer 27 is a mosaic element. By changing the position and the number of the openings 60, the distribution ratio of light to the waveguide 28 and the waveguide 29 can be adjusted. As in the example of FIG. 6, the distribution ratio is, for example, 1:1. In the wavelength range including the C-band and the L-band, light having substantially equal intensity can be output to the waveguide 28 and the waveguide 29.

As illustrated in FIG. 6, the intensity of light reflected from the multiplexer 27 to the waveguides 22 and 25 is lower than the light transmitted to the waveguides 28 and 29. The spectral line width is hardly expanded, and the monochromaticity of the laser beam is improved. The distribution ratio of the multiplexer 27 may be other than 1:1. The number of output ends of the multiplexer 27 may be two, one, or three or more. The multiplexer 27 may be formed of a plurality of waveguides. For example, the multiplexer may be formed of a first waveguide connecting the waveguide 22 and the waveguide 28 and a second waveguide connecting the waveguide 29 and the waveguide 25. The first waveguide and the second waveguide may form a directional coupler.

The wavelength of light can be adjusted by inputting power to the heater 37 provided in the ring resonator 30 and the heater 38 provided in the ring resonator 32. The region 16 and the region 18 of the optical filter 11 share the ring resonator 30 and the ring resonator 32, and the heater 37 and the heater 38. The relationship between the power of the heater and the amount of change in the wavelength is investigated for each heater. Both the wavelength of light in the region 16 and the wavelength of light in the region 18 can be controlled by the heater 37 and the heater 38.

The substrate 10 is an SOI substrate and has the silicon layer 46. The waveguide, the ring resonator, and the multiplexer 27 are provided in the silicon layer 46. By confining light in a silicon waveguide or the like, the loss of light can be reduced. The ring resonator of silicon is heated by the heater to change the refractive index, thereby adjusting the wavelength of light. The substrate 10 may be other than the SOI substrate, and may have, for example, a silicon nitride (SiN) layer. The waveguide, the ring resonator, and the multiplexer 27 may be provided in the SiN layer.

The gain section 12 and the gain section 14 are light emitting elements formed of a group III-V compound semiconductor. The wavelengths of the light emitted from the gain section 12 and the gain section 14 are determined by the composition of the active layer 54 and the like. The wavelength range of the light emitted from the gain section 12 is different from the wavelength range of the light emitted from the gain section 14. For example, the wavelength range of the gain section 12 covers the C-band. The wavelength range of the gain section 14 covers the L-band. The wavelength range of the wavelength tunable laser 100 may be other than the C-band and the L-band.

### Second Embodiment

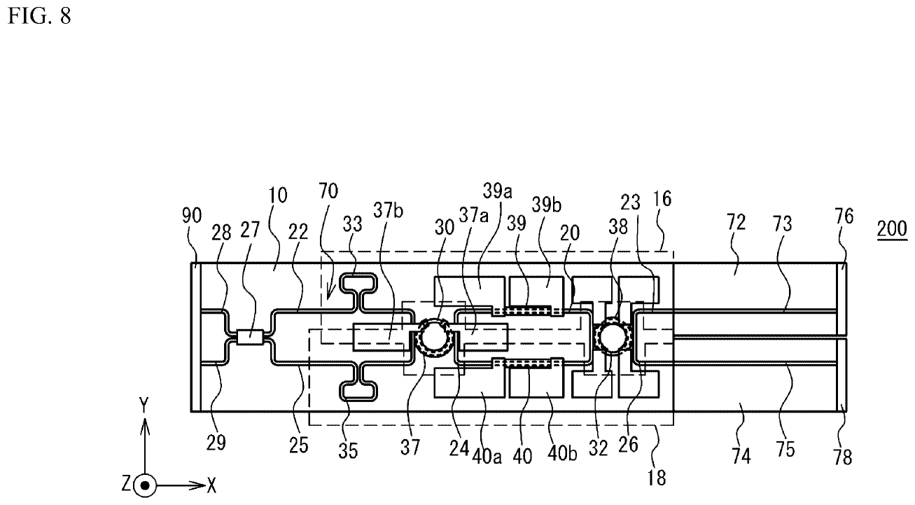

FIG. 8 is a plan view illustrating a wavelength tunable laser 200 according to a second embodiment. The description of the same configuration as that of the first embodiment will be omitted.

The wavelength tunable laser 200 includes an optical filter 70, a gain section 72 (first gain section), and a gain section 74 (second gain section). The optical filter 70 is formed at the substrate 10. No loop mirror is provided in the waveguide 23 and the waveguide 26 of the optical filter 70. The waveguide 23 and the waveguide 26 extend to one end portion of the substrate 10 in the X-axis direction. The heater 38 is provided in the ring resonator 32. Four pads are connected to the heater 38.

The gain section 72 and the gain section 74 are semiconductor chips formed of, for example, a group III-V compound semiconductor. The gain section 72 and the gain section 74 are disposed outside the substrate 10, and are placed against one end portion of the substrate 10 and are butt-joint joined.

The gain section 72 has a waveguide 73. The waveguide 73 is formed of an active layer, a cladding layer, and the like. The waveguide 73 is parallel to the X-axis and extends from the first end portion to the second end portion of the gain section 72. The gain section 74 has a waveguide 75. The configuration of the waveguide 75 is the same as that of the waveguide 73.

The waveguide 73 of the gain section 72 faces an end portion of the waveguide 23 of the optical filter 70 and is optically coupled to the waveguide 23. The waveguide 75 of the gain section 74 faces the end portion of the waveguide 24 and is optically coupled to the waveguide 24.

A high reflection coat (HR coat) 76 is provided at an end portion of the gain section 72 opposite to the substrate 10. The high reflection coat 76 (second reflection portion) covers the end portion of the waveguide 73 of the gain section 72. A high reflection coat 78 (fourth reflection portion) is provided at an end portion of the gain section 74 opposite to the substrate 10. The high reflection coat 78 covers the end portion of the waveguide 75 of the gain section 74. The antireflection coat (AR coat) 90 may be provided between the gain section 72 and the substrate 10 and between the gain section 74 and the substrate 10.

The light generated by the active layer of the gain section 72 propagates through the waveguide 73. The light emitted from the gain section 72 has a wavelength in the C-band, for example. The light emitted from the gain section 74 has a wavelength in the L-band, for example. The light emitted from the gain section 72 is input to the waveguide 23 and propagates through the region 16 of the optical filter 70. The light emitted from the gain section 72 is reflected from the loop mirror 33 and the high reflection coat 76, and travels back and forth between the loop mirror 33 and the high reflection coat 76 to occur laser oscillation. The laser light is output from the waveguide 28 and the waveguide 29.

The light generated by the active layer of the gain section 74 propagates through the waveguide 75. The light emitted from the gain section 74 is input to the waveguide 26 and propagates through the region 18 of the optical filter 70. The light emitted from the gain section 74 is reflected from the loop mirror 35 and the high reflection coat 78, and travels back and forth between the loop mirror 35 and the high reflection coat 78 to occur laser oscillation. The laser light is output from the waveguide 28 and the waveguide 29.

According to the second embodiment, the wavelength tunable laser 200 includes the optical filter 70, and the two gain sections 72 and 74. The region 16 and the gain section 72 of the optical filter 70 form a laser resonator corresponding to, for example, the C-band. The region 18 and the gain section 74 of the optical filter 70 form a laser resonator corresponding to, for example, the L-band. The wavelength tunable laser 200 can cover the C-band and L-band. The region 16 and the region 18 share the ring resonator 30 and the ring resonator 32. The configuration is simplified, and the wavelength tunable laser 200 can be downsized.

### Third Embodiment

The region 16 of the wavelength tunable laser has the waveguide 20 and the gain section 12, and generates laser light in the C-band (from 1530 nm to 1565 nm, first band). The band gap of the active layer of the gain section 12 has a size corresponding to the C-band. The region 18 has the waveguide 24 and the gain section 14, and generates laser light in the L-band (from 1565 nm to 1625 nm, second band). The band gap of the active layer 54 of the gain section 14 has a size corresponding to the L-band and is narrower than the band gap of the gain section 12.

The waveguide 20 and the waveguide 24 form a loop-type waveguide (loop waveguide). Light in the C-band may leak from the region 16 to the waveguide 24. Light in the L-band may leak from the region 18 to the waveguide 20. The active layer 54 of the gain section 14 absorbs light in the C-band. It is difficult for the light in the C-band to circulate through the loop waveguide. The active layer 54 of the gain section 12 is less likely to absorb the light in the L-band. In a case where a band-pass filter 80 is not provided, the light in the L-band circulates through the loop waveguide. Thus, an unintended Fabry-Perot oscillation may occur. In the third embodiment, such unnecessary oscillation is prevented.

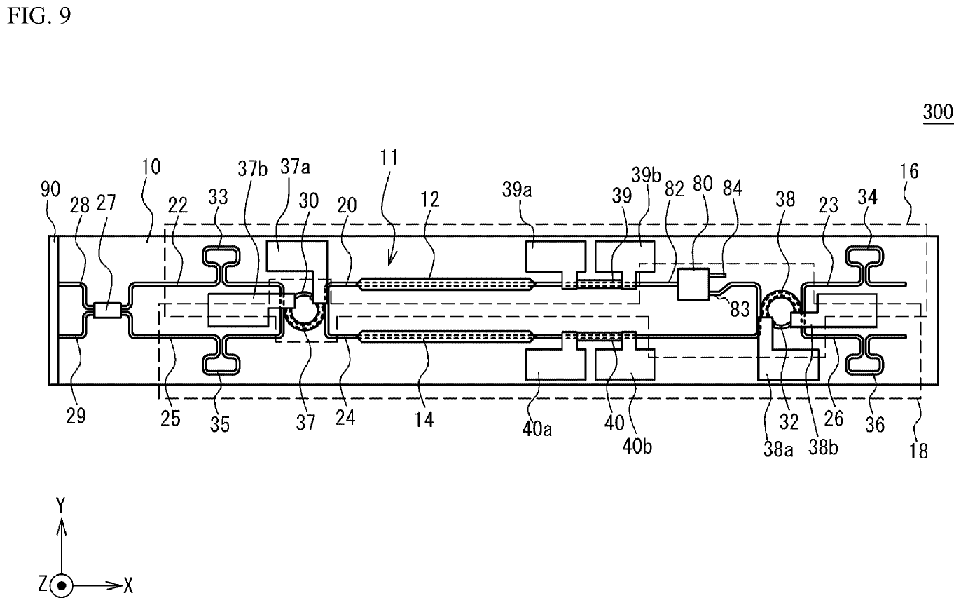

FIG. 9 is a plan view illustrating a wavelength tunable laser 300 according to a third embodiment. Description of the same configuration as that of either the first embodiment or the second embodiment will be omitted. As illustrated in FIG. 9, the wavelength tunable laser 300 has the band-pass filter 80. The band-pass filter 80 is provided in the waveguide 20, and is located, for example, between the heater 39 and the ring resonator 32 of the waveguide 20. Other configurations of wavelength tunable laser 300 are the same as those of the wavelength tunable laser 100 of FIG. 1.

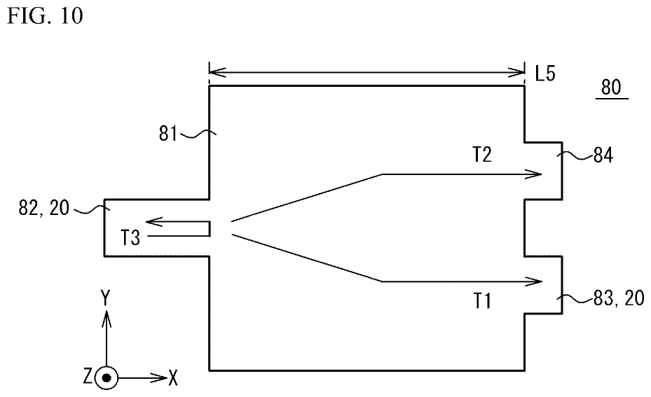

FIG. 10 is a plan view illustrating the band-pass filter 80. Both the band-pass filter 80 and the multiplexer 27 of FIG. 5A are referred to as mosaic elements, but they have different functions. The multiplexer 27 of FIG. 5A is a multiplexer intended to equally transmit both light in the C-band and light in the L-band. On the other hand, the band-pass filter 80 is similar to the multiplexer 27 in appearance with one input and two outputs, but the wavelength dependence of the transmittance is different between the path of T1 and the path of T2 in FIG. 10, and the band-pass filter 80 functions as a filter for wavelength selection. The details thereof will be described later. The band-pass filter 80 includes a region 81, a port 82 (first port), a port 83 (second port), and a port 84 (third port). The planar shape of the region 81 is, for example, rectangular. A length L5 of one side of the region 81 is, for example, 10 μm. The region 81 is provided with an opening as in the multiplexer 27.

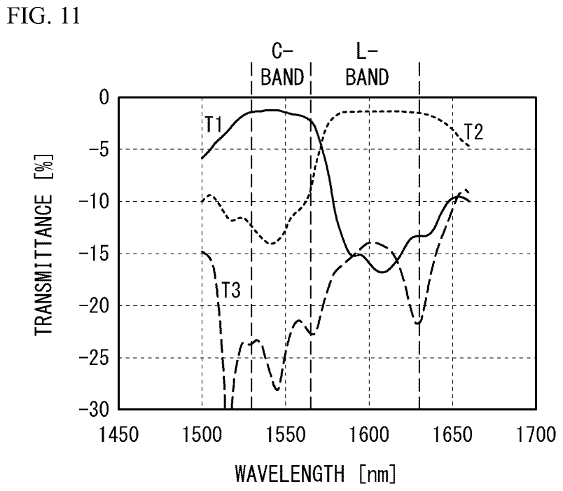

The first end portion and the second end portion of the region 81 face each other. The port 82 is provided at the first end portion. The port 83 and the port 84 are provided at the second end portion. The port 82 is an input port. The port 83 and the port 84 are output ports. The port 82 and the port 83 are connected to the waveguide 20. The port 84 is not connected to the waveguide of the wavelength tunable laser 300, and extends to a position away from the waveguide 20 and the waveguide 24, for example, and terminates. T1, T2 and T3 are described in FIG. 11.

FIG. 11 is a diagram illustrating transmittance. The horizontal axis represents the wavelength of light. The vertical axis represents the transmittance of light. The transmittance of light input from the port 82 and transmitted from the port 83 is denoted by T1 and represented by a solid line. The transmittance of light input from the port 82 and transmitted from the port 84 is denoted by T2 and represented by a dotted line. Light is input from the port 82, and the reflectance of the light reflected to the port 82 is denoted by T3 and represented by a dashed line. Dashed lines in FIG. 11 represent the C-band (from 1530 nm to 1565 nm) and the L-band (from 1565 nm to 1625 nm).

As illustrated in FIG. 11, a transmittance T1 from the port 82 to the port 83 is high in the C-band and low in the L-band. A transmittance T2 from the port 82 to the port 84 is low in the C-band and high in the L-band. A reflectance T3 back to the port 82 is lower than the transmittance T1 and the transmittance T2 at most wavelengths.

In the L-band, the transmittance T2 between the port 82 and the port 84 is higher than the transmittance T1 between the port 82 and the port 83. The light in the L-band leaking from the region 18 to the waveguide 20 is less likely to propagate through the port 83 and is output from the port 84. The port 84 is not connected to the waveguide 20. The light in the L-band does not circulate through the waveguide 20 and the waveguide 24. Abnormal oscillation is less likely to occur.

In the C-band, the transmittance T1 is higher than the transmittance T2. The light in the C-band generated in the region 16 is less likely to propagate through the port 84 and is likely to propagate through the port 83. The light in the C-band transmits through the band-pass filter 80, and propagates through the waveguide 20 to occur laser oscillation. The band-pass filter 80 is less likely to affect the laser oscillation in the region 16.

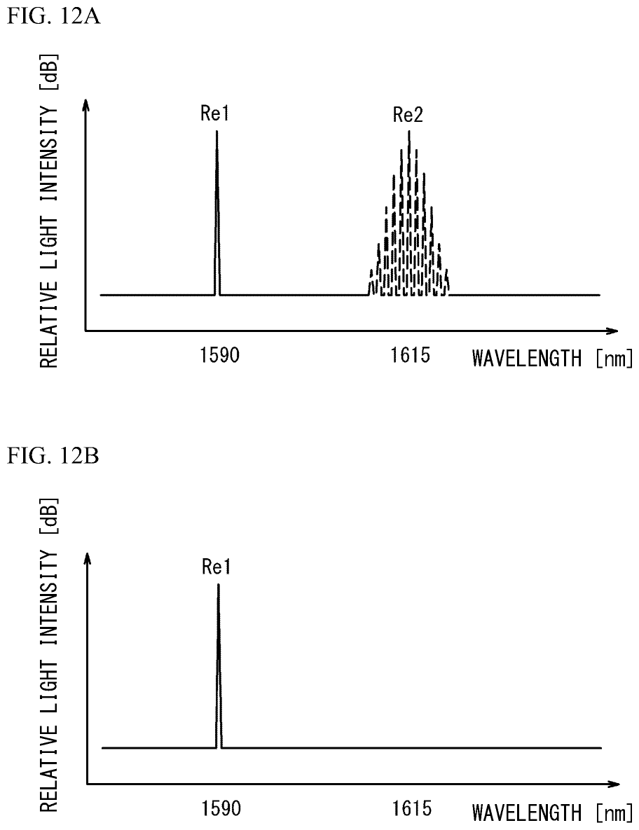

FIGS. 12A and 12B are diagrams illustrating optical spectra when only a laser portion of an L-band is driven without driving a laser portion of a C-band. The horizontal axis represents the wavelength of light, and represents the wavelength band of the L-band. The vertical axis represents relative light intensity. The gain section 14 of the region 18 is operated with the target wavelengths as 1590 nm. The gain section 12 of the region 16 is not operated.

In the example of FIG. 12A, the band-pass filter 80 is not provided. Oscillation Re1 and oscillation Re2 are occurred. The oscillation Re1 is located near 1590 nm and is represented by a solid line. The oscillation Re2 is located near 1615 nm and is represented by a dotted line. The oscillation Re1 is a normal oscillation. On the other hand, the oscillation Re2 is an unintended Fabry-Perot oscillation (abnormal oscillation) caused by light circulating through the waveguide 20 and the waveguide 24.

In the example of FIG. 12B, the band-pass filter 80 is provided in the waveguide 20. The normal oscillation Re1 is occurred. Since the band-pass filter 80 cuts off the L-band, no abnormal oscillation Re2 is occurred.

According to the third embodiment, the band-pass filter 80 is provided in the waveguide 20 of the region 16. The port 82 and the port 83 are connected to the waveguide 20. The port 84 is not connected to the waveguide 20. In the C-band, the transmittance T1 between the port 82 and the port 83 is higher than the transmittance T2 between the port 82 and the port 84. The light in the C-band generated in the region 16 transmits through the band-pass filter 80 to occur laser oscillation. In the L-band, the transmittance T2 is higher than the transmittance T1. The light in the L-band propagating through the waveguide 20 is less likely to propagate through the port 83 of the band-pass filter 80, and propagates through the port 84. The band-pass filter 80 cuts off the light in the L-band and the light is less likely to circulate through the waveguide 20 and the waveguide 24. Abnormal oscillation can be prevented.

The L-band is a band of a longer wavelength than the C-band. The C-band is a band of a shorter wavelength than the L-band. The active layer 54 of the gain section 14 has a high absorptance for the light in the C-band. The gain section 14 absorbs light leaking from the region 16 to the region 18. Abnormal oscillation is less likely to occur.

The band-pass filter 80 may be a mosaic element or an element other than the mosaic element. The band-pass filter 80 of the mosaic element can be downsized to, for example, about 10 μm×10 μm. The band-pass filter 80 may be provided at any position of the waveguide 20.

### Fourth Embodiment

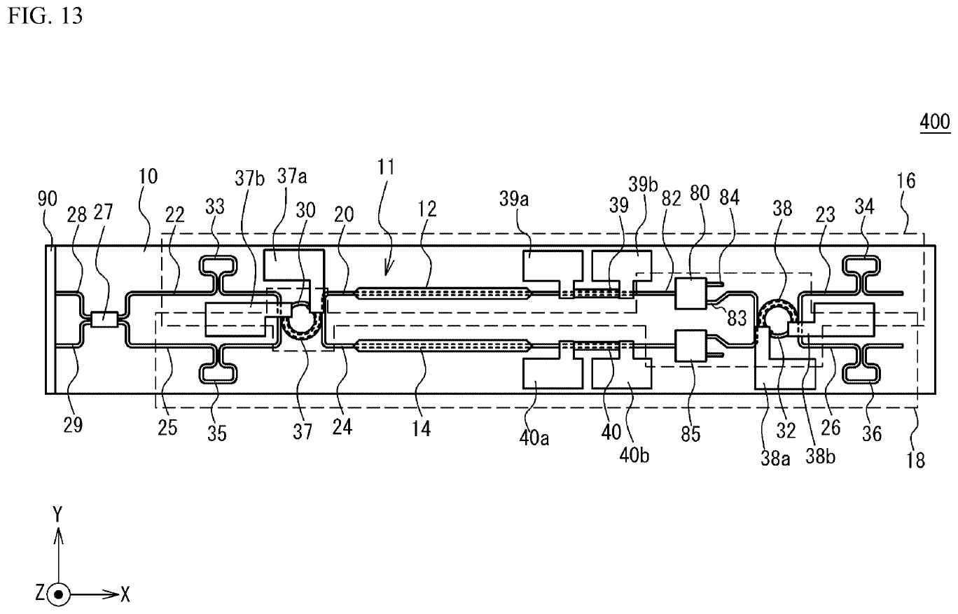

FIG. 13 is a plan view illustrating a wavelength tunable laser 400 according to a fourth embodiment. The description of the same configuration as that of any of the first embodiment to the third embodiment will be omitted.

The band-pass filter 80 is provided in the waveguide 20 of the region 16. A band-pass filter 85 is provided in the waveguide 24 of the region 18. The band-pass filter 80 and the band-pass filter 85 are mosaic elements, for example, and are both filters with one input and two outputs.

The input port of the band-pass filter 85 is connected to the waveguide 24. The first output port of the band-pass filter 85 is connected to the waveguide 24. The second output port is not connected to the waveguide 24. The transmittance between the input port and the first output port of the band-pass filter 85 is low in the C-band and high in the L-band as represented by T2 in FIG. 11. The transmittance between the input port and the second output port is high in the C-band and low in the L-band, as represented by T1 in FIG. 11.

According to the fourth embodiment, the light in the L-band transmits through the band-pass filter 85 to occur laser oscillation. The light in the C-band may leak from the region 16 to the waveguide 24. Such light is absorbed in the gain section 14 and propagates through the second output port of the band-pass filter 85, and does not circulate through the waveguide 24 and the waveguide 20. Abnormal oscillation can be prevented.

Although the embodiments of the present disclosure have been described in detail, the present disclosure is not limited to the specific embodiments, and various modifications and changes can be made within the scope of the gist of the present disclosure described in the claims. For example, the multiplexer 27 may be a directional coupler. In this case, the multiplexer 27 is formed of a plurality of waveguides. For example, the directional coupler may be formed by a first waveguide connecting the waveguide 22 and the waveguide 28, and a second waveguide connecting the waveguide 29 and the waveguide 25.

What is claimed is::

1. A wavelength tunable laser comprising:
a first gain section having an optical gain and emitting light of a first band;
a second gain section having an optical gain and emitting light of a second band;
an optical filter provided at a substrate;
a first reflection portion and a second reflection portion, each of which reflects the light of the first band; and
a third reflection portion and a fourth reflection portion, each of which reflects the light in the second band, wherein
the optical filter includes a first region configured to allow the light of the first band to propagate, a second region configured to allow the light of the second band to be propagated, a first ring resonator, and a second ring resonator,
the first gain section is optically coupled to the first region,
the second gain section is optically coupled to the second region,
the first region includes a first waveguide, a second waveguide, and a third waveguide,
the second region includes a fourth waveguide, a fifth waveguide, and a sixth waveguide,
each of the first waveguide and the fourth waveguide is optically coupled to the first ring resonator and the second ring resonator,
each of the second waveguide and the fifth waveguide is optically coupled to the first ring resonator,
each of the third waveguide and the sixth waveguide is optically coupled to the second ring resonator,
the first waveguide, the first ring resonator, and the second ring resonator are provided between the first reflection portion and the second reflection portion in a propagating direction of light, and
the fourth waveguide, the first ring resonator, and the second ring resonator are provided between the third reflection portion and the fourth reflection portion in a propagating direction of light.

2. The wavelength tunable laser according to claim 1, wherein
the first waveguide and the second waveguide are located opposite each other across the first ring resonator and extend in a same direction from the first ring resonator,
the fourth waveguide and the fifth waveguide are located opposite each other across the first ring resonator and extend in a same direction from the first ring resonator,
the first waveguide and the third waveguide are located opposite each other across the second ring resonator and extend in a same direction from the second ring resonator, and
the fourth waveguide and the sixth waveguide are located opposite each other across the second ring resonator and extend in a same direction from the second ring resonator.

3. The wavelength tunable laser according to claim 1, wherein
the fourth waveguide extends from the first ring resonator and the second ring resonator in a direction opposite to a direction in which the first waveguide extends,
the fifth waveguide extends from the first ring resonator in a direction opposite to a direction in which the second waveguide extends, and
the sixth waveguide extends from the second ring resonator in a direction opposite to a direction in which the third waveguide extends.

4. The wavelength tunable laser according to claim 1, wherein
the first reflection portion is a loop mirror provided in the second waveguide,
the second reflection portion is a loop mirror provided in the third waveguide,
the third reflection portion is a loop mirror provided in the fifth waveguide,
the fourth reflection portion is a loop mirror provided in the sixth waveguide,
the first gain section and the second gain section are bonded to one surface of the substrate,
the first gain section is provided at a position overlapping the first waveguide and is optically coupled to the first waveguide, and
the second gain section is provided at a position overlapping the fourth waveguide and is optically coupled to the fourth waveguide.

5. The wavelength tunable laser according to claim 1, wherein
the first reflection portion is a loop mirror provided in the second waveguide,
the third reflection portion is a loop mirror provided in the fifth waveguide,
the first gain section and the second gain section are butt-jointed to the substrate,
the first gain section is optically coupled to the third waveguide,
the second gain section is optically coupled to the sixth waveguide,
the second reflection section is a reflection coat provided opposite the optical filter with respect to the first gain section, and
the fourth reflection portion is a reflection coat provided opposite the optical filter with respect to the second gain section.

6. The wavelength tunable laser according to claim 1, wherein the optical filter includes a multiplexer, a seventh waveguide and an eighth waveguide, the second waveguide is optically coupled to a first input end of the multiplexer, the fifth waveguide is optically coupled to a second input end of the multiplexer, the seventh waveguide is optically coupled to a first output end of the multiplexer, and the eighth waveguide is optically coupled to a second output end of the multiplexer.

7. The wavelength tunable laser according to claim 6, wherein
the multiplexer is a mosaic element.

8. The wavelength tunable laser according to claim 1, further comprising:
a first heater provided on the first ring resonator; and
a second heater provided on the second ring resonator.

9. The wavelength tunable laser according to claim 1, wherein
the substrate has a silicon layer or a silicon nitride layer, and
the first waveguide, the second waveguide, the third waveguide, the fourth waveguide, the fifth waveguide, the sixth waveguide, the first ring resonator, and the second ring resonator are provided in the silicon layer or the silicon nitride layer.

10. The wavelength tunable laser according to claim 1, wherein
the second band is a band having a longer wavelength than the first band,
the wavelength tunable laser includes a band-pass filter,
the band-pass filter has a first port, a second port, and a third port,
the first port and the second port are connected to the first waveguide,
in the first band, a transmittance between the first port and the second port is higher than a transmittance between the first port and the third port, and
in the second band, a transmittance between the first port and the third port is higher than a transmittance between the first port and the second port.

11. The wavelength tunable laser according to claim 10, wherein
the band-pass filter is a mosaic element.

12. An optical filter comprising:
a first region;
a second region;
a first ring resonator; and
a second ring resonator, wherein
the first region includes a first waveguide, a second waveguide, and a third waveguide,
the second region includes a fourth waveguide, a fifth waveguide, and a sixth waveguide,
each of the first waveguide and the fourth waveguide is optically coupled to the first ring resonator and the second ring resonator,
each of the second waveguide and the fifth waveguide is optically coupled to the first ring resonator, and
each of the third waveguide and the sixth waveguide is optically coupled to the second ring resonator.
